(19) United States
(12) Patent Application Publication
(10) Pub. No.: US 2008/0246519 A1
(43) Pub. Date: Oct. 9, 2008

(54) GATE DRIVE CIRCUIT

(75) Inventors: Mio SUZUKI, Niiza-shi (JP); Hiroshi Takahashi, Niiza-shi (JP); Masao Ueno, Niiza-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Sanken Electric Co., Ltd., Niiza-shi (JP)

(21) Appl. No.: 12/061,270

(22) Filed: Apr. 2, 2008

(30) Foreign Application Priority Data
Apr. 3, 2007 (JP) 2007-097309

(51) Int. Cl. H03L 7/00

(52) U.S. Cl. 327/141

(57) ABSTRACT

A gate drive circuit including dead time control circuits delaying on periods of switching elements S1, S2 based on a control signal; driving circuits; and monitor circuits. Each of the monitor circuits includes a current source and an N-type FET in which the source is connected to the gate of one of the switching elements; the drain is connected to the current source; and a predetermined voltage is applied to the gate. When an off state of one of the switching elements is detected, the N-type FET Qn outputs an off signal to the dead time control circuit on the other switching element side. Based on the off signal, the dead time control circuit on the other switching element side terminates an operation of delaying the on period of the other switching element.

### BACKGROUND OF THE INVENTION

The present invention relates to a gate drive circuit to prevent two switching elements connected in series from simultaneously conducting electricity.

FIG. 1 is a diagram illustrating a first example of a related gate drive circuit. FIG. 2 is an operation waveform diagram of the first example of the related gate drive circuit. In FIG. 1, a series circuit of a switching element S1 composed of a MOSFET and a switching element S2 composed of a MOSFET is connected to between a DC power supply voltage VDD and the ground. This gate drive circuit turns on and off alternately the switching elements S1 and S2 based on a control signal Vin and intermittently outputs the DC power supply voltage VDD to a terminal OUT. The gate drive circuit includes an inverter 1, dead time control circuits 2 and 4, a low side driver 3, a level shift circuit 5, and a high side driver 6.

The inverter 1 inverts the control signal Vin and outputs the same to the dead time control circuit 2. When the control signal Vin is Low (L level), the dead time control circuit 2 delays the control signal Vin by a predetermined period of time TD and outputs the same. When the control signal Vin is High (H level), the dead time control circuit 2 immediately outputs Low (L level). The low side driver 3 applies an on signal to the switching element S2 when the signal from the dead time control circuit 2 is high (H level) and applies an off signal to the switching element S2 when the signal from the dead time control circuit 2 is low (L level).

The dead time control circuit 4 delays the control signal Vin by the predetermined time TD and outputs the same when the control signal Vin is high and immediately outputs low when the control signal Vin is low. The high side driver 6 applies an on signal to the switching element S1 when the signal from the dead time control circuit 4 is high and applies an off signal to the switching element S1 when the signal from the dead time control circuit 4 is low.

The potential of the source of the switching element S1 varies depending on the on/off state of the switching element S2, and accordingly the level shift circuit 5 converts the signal outputted to the switching element S1. The high side driver 6 includes a bootstrap circuit or the like to generate power supply voltage Vcc1 and drives the switching element S1.

A description will be given of an operation of the gate drive circuit with reference to FIGS. 1 and 2. First, when the control signal Vin goes high, the control signal Vin is inverted by the inverter 1 into an L level signal and is inputted to the dead time control circuit 2. The dead time control circuit 2 outputs the L level signal through the low side driver 3 to the gate of the switching element S2. The gate of the switching element 2 has a parasitic capacitance and is therefore not immediately turned off.

When charges (holes) stored at the gate of the switching element S2 are discharged through the low side driver 3 and a gate voltage VG2 is reduced to a threshold value VTH2 or less, the switching device S2 is turned off. The inputted control signal Vin is high, and the dead time control circuit 4 outputs high after a predetermined delay time TD. The high side driver 6 outputs high to the gate terminal of the switching element S1 to turn on the switching element S1. When the control signal Vin goes low, the output of the high side driver 6 goes low. When the gate voltage VG1 is reduced to the threshold value VTH1 or less, the switching element S1 is turned off, and the switching element S2 is turned on by the dead time control circuit 2 after the predetermined delay time TD elapses.

After the control signal goes high, there is a delay before the switching element S2 is turned off. Accordingly, when the switching element S1 is immediately turned on, both the switching elements S1 and S2 are simultaneously on in some cases. After the control signal goes low, there is also a delay before the switching element S1 is turned off. Accordingly, the predetermined delay times TD of the dead time control circuits 2 and 4 are set so that both the switching elements S1 and S2 are not simultaneously on.

However, in order to prevent the switching elements S1 and S2 from being simultaneously on independently of variations and changes of the characteristics of the switching elements S1 and S2, the predetermined delay time TD of the dead time control circuits 2 and 4 should be set large. This delay time TD is a period of time when both the switching elements are off and is preferably as small as possible for improving the performance of the circuit.

For example, as a related technical literature, the Japanese Patent Laid-open Publication No. 03-169273 disclosed a circuit which monitors on/off states of the switching elements S1 and S2 and turns on one of the switching elements S1 and S2 immediately after the other switching element S1 or S2 is turned off. According to the above related technical literature, as illustrated in FIG. 3, the circuit includes monitor circuits 7 and 8 which monitor the on/off states of the switching elements S1 and S2 and output monitor signals. For example, when an instruction signal to specify on or off of one of the switching elements is on and the monitoring signal of the monitor circuit of the other switching element is off, the circuit outputs a drive signal to turn on the one switching element to one of the dead time control circuits and gives the same to the one switching element.

### SUMMARY OF THE INVENTION

However, in the aforementioned related art, each of the monitor circuits 7 and 8 monitoring the on/off states of the switching elements S1 and S2 includes an inverter or a comparator composed of N-type and P-type FETs Qn and Qp. Accordingly, rapidly turning on/off the switching elements S1 and S2 causes chattering (overshoot and ringing) as illustrated in FIG. 4 in the monitoring signals of the monitor circuits 7 and 8. The on/off states of the switching elements S1 and S2 therefore cannot be accurately monitored in some cases.

In FIG. 4, in order to detect the threshold value VTH of the output stage of about 2V while the gate voltage Vg is 9 to 12 V, it is necessary to increase the size of the N-type FET Qn of each monitor circuit and reduce the size of the P-type FET Qp of the same. However, such a matter is difficult.

According to the present invention, it is possible to provide a gate drive circuit which includes monitor circuits of a simple structure and does not cause chattering in monitoring signals even at rapid turning on and off of the switching elements.

According to a first technical aspect of the present invention, a gate drive circuit is a gate drive circuit which based on a control signal, turns on/off alternately first and second switching elements connected in series and includes: a first dead time control circuit delaying an on period of the first switching element based on the control signal to generate a period when both the first and second switching elements are off; a second dead time control circuit delaying an on period of the second switching element based on the control signal to generate a period when both the first and second switching elements are off; a first drive circuit driving the first switching element based on a signal from the first dead time control circuit; a second drive circuit driving the second switching element based on a signal from the second dead time control circuit; a first monitor circuit monitoring an on/off state of the first switching element; and a second monitor circuit monitoring an on/off state of the second switching element. Each of the first and second monitor circuits includes a current source and a detector transistor in which a first electrode is connected to a control terminal of one of the switching elements; a second electrode is connected to the current source; and a predetermined voltage is applied to a first control electrode. When an off state of the one switching element is detected, the detector transistor outputs an off signal to the dead time control circuit on the other switching element side. Based on the off signal, the dead time control circuit on the other switching element side terminates an operation of delaying the on period of the other switching element.

According to a second technical aspect of the present invention, in addition to the first technical aspect, the gate drive circuit is characterized in that the detector transistor is a MOSFET and the voltage applied to the first control electrode of the detector transistor is not less than total voltage of gate threshold voltage of the switching element and gate threshold voltage of the detector transistor.

According to a third technical aspect of the present invention, in addition to the first technical aspect, the gate drive circuit is characterized in that the detector transistor is a bipolar transistor and the voltage applied to the base of the detector transistor is not less than total voltage of gate threshold voltage of the switching element and base threshold voltage of the detector transistor.

According to a fourth technical aspect of the present invention, in addition to the first technical aspect, the gate drive circuit is characterized in that each of the monitor circuits includes a shutoff unit having: a third electrode connected to a power source; a fourth electrode connected to the first control electrode of the detector transistor; and a second control electrode. The shutoff unit applies power supply voltage to the first control electrode of the detector transistor while the signal from the other monitor circuit is inputted to the second control electrode and shuts off the power supply voltage applied to the first control electrode of the detector transistor while the signal from the other monitor circuit is not inputted to the second control electrode.

According to a fifth technical aspect of the present invention, in addition to the first to third technical aspects, the gate drive circuit is characterized in that each of the monitor circuits includes a short circuit unit having: a fifth electrode connected to the first control electrode of the detector transistor; a sixth electrode; and a third control electrode. The short-circuit unit applies the power supply voltage to the first control electrode of the detector transistor while the signal from the other monitor circuit is inputted into the third control electrode and short-circuits the first control electrode of the detector transistor while the signal from the other monitor circuit is not inputted into the third control electrode.

According to a sixth technical aspect of the present invention, in addition to the first to third technical aspects, the gate drive circuit is characterized in that each of the monitor circuits includes a shutoff unit having: a third electrode connected to a power source; a fourth electrode connected to the first control electrode of the detector transistor; and a second control electrode. The shutoff unit applies power supply voltage to the first control electrode of the detector transistor while the control signal is inputted to the second control electrode and shuts off the power supply voltage applied to the first control electrode of the detector transistor while the control signal is not inputted to the second control electrode.

According to a seventh technical aspect of the present invention, in addition to the first to third technical aspects the gate drive circuit is characterized in that each of the monitor circuits includes a short circuit unit having: a fifth electrode connected to the first control electrode of the detector transistor; a sixth electrode; and a third control electrode. The short-circuit unit applies power supply voltage to the first control electrode of the detector transistor when the control signal is inputted to the third control electrode and short-circuits the first control electrode of the detector transistor when the control signal is not inputted to the third control electrode.

According to a eighth technical aspect of the present invention, in addition to the fourth or sixth technical aspect, the gate drive circuit is characterized in that each of the monitor circuits includes a stabilization circuit which is connected to the fourth electrode of the shutoff unit and stabilizes voltage applied to the fourth electrode of the shutoff unit.

### BRIEF DESCRIPTION OF THE DRAWINGS

FIG. 1 is a diagram illustrating a first example of a related gate drive circuit.

FIG. 2 is an operation waveform diagram of the first example of the related gate drive circuit.

FIG. 3 is a diagram illustrating a second example of the related gate drive circuit.

FIG. 4 is an operation waveform diagram of the second example of the related gate drive circuit.

FIG. 5 is a diagram, illustrating a first example of a gate drive circuit according to a first embodiment of the present invention.

FIG. 6 is a diagram illustrating a second example of the gate drive circuit according to the first embodiment of the present invention.

FIG. 7 is a diagram illustrating a third example of the gate drive circuit according to the first embodiment of the present invention.

FIG. 8 is a diagram illustrating a fourth example of the gate drive circuit according to the first embodiment of the present invention.

FIGS. 9A and 9B illustrating an operation waveform diagram of the gate drive circuit according to the first embodiment of the present invention.

FIG. 10 is a diagram illustrating a gate drive circuit according to a second embodiment of the present invention.

FIG. 11 is a diagram illustrating a gate drive circuit according to a third embodiment of the present invention.

FIG. 12 is a diagram illustrating a gate drive circuit according to a fourth embodiment of the present invention.

FIG. 13 is an operation waveform diagram of the gate drive circuit according to the fourth embodiment of the present invention.

FIG. 14 is a diagram illustrating a gate drive circuit according to a fifth embodiment of the present invention.

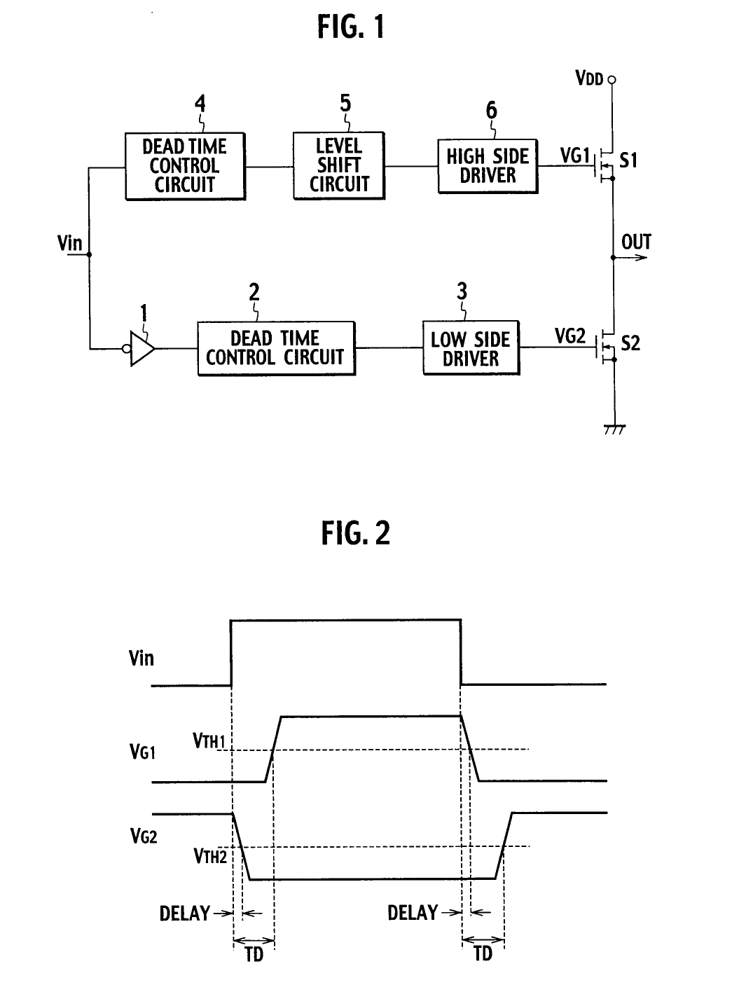

### DESCRIPTION OF THE PREFERRED EMBODIMENTS

A description will be given of embodiments of the gate drive circuit of the present invention in detail with reference to the drawings. The components being the same or equivalent to those of the gate drive circuits described in the related art are given the same reference numerals as those used in the explanation of the related art.

### First Embodiment

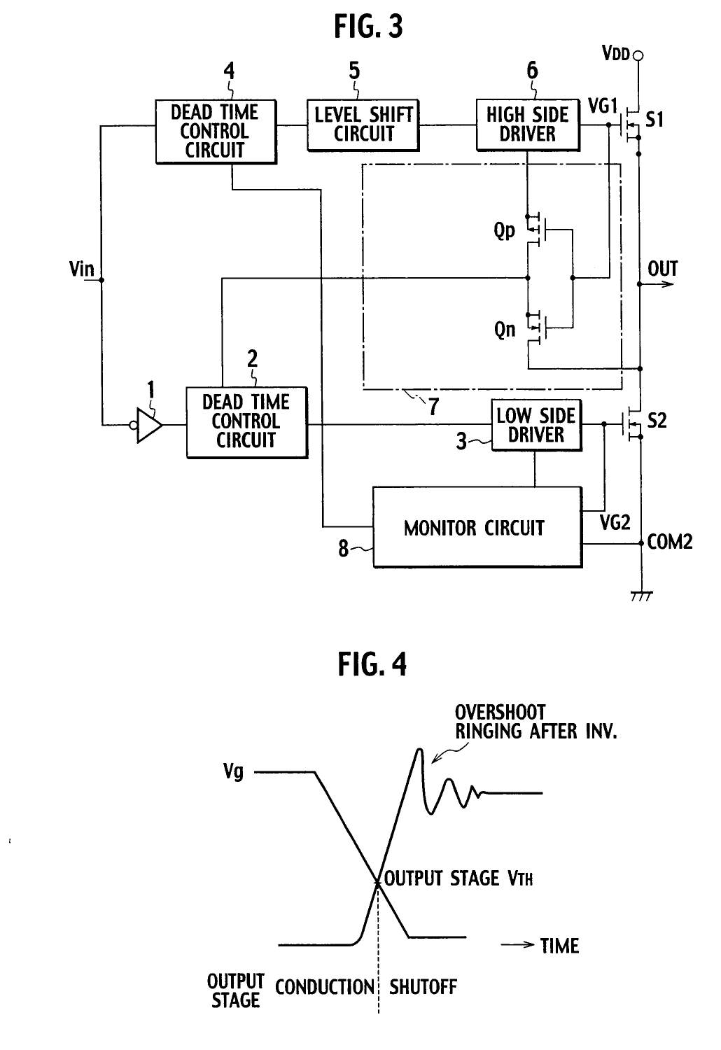

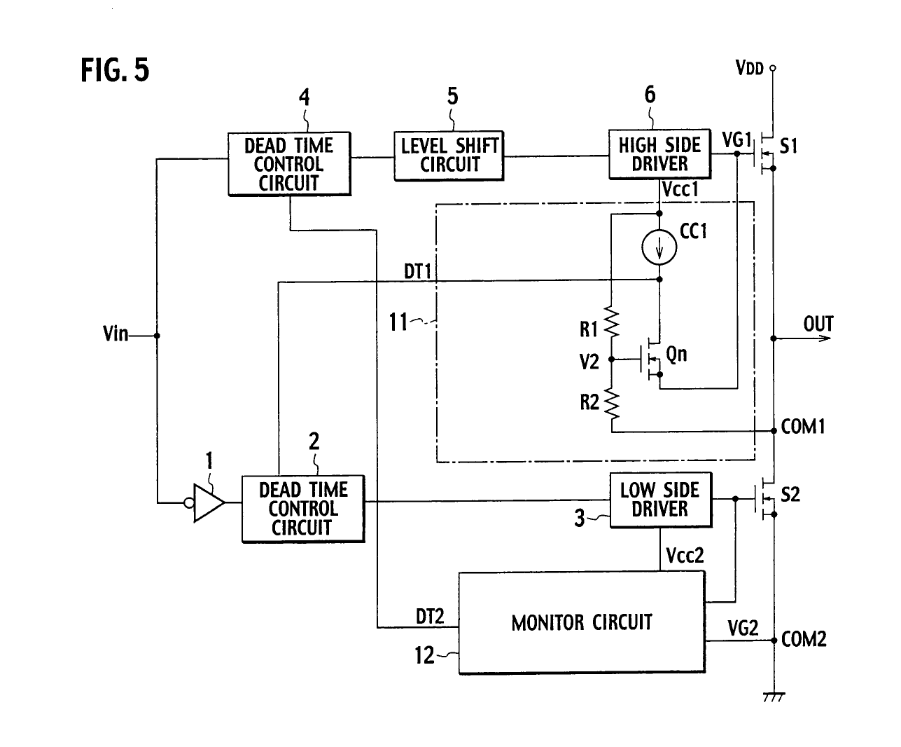

FIG. 5 is a diagram illustrating a first example of a gate drive circuit according to a first embodiment of the present invention. The gate drive circuit illustrated in FIG. 5 is characterized by including monitor circuits 11 and 12 instead of the monitor circuits 7 and 8 of the gate drive circuit as illustrated in FIG. 3. The other constitution illustrated in FIG. 5 is the same as that illustrated in FIG. 3. The same components are given the same reference numerals, and the description thereof is omitted.

The monitor circuit 11 includes a current source CC1, resistors R1 and R2, and an N-type MOSFET (N-type FET) Qn as a detector detecting an OFF state of a switching element S1. The current source CC1 may be a resistor or a current mirror circuit. Using the current source CC1 which is a constant current source allows more accurate detection of the on/off states of the switching elements S1 and S2.

An end of the current source CC1 is connected to power supply voltage Vcc1 of a high side driver 6, and the other end thereof is connected to the drain of the N-type FET Qn and the dead time control circuit 2. The source of the N-type FET Qn is connected to the gate of the switching element S1. A series circuit of the resistors R1 and R2 is connected to between a connection point of the switching elements S1 and S2 and the power supply voltage Vcc1, and the connection point of the resistors R1 and R2 is connected to the gate of the N-type FET Qn. The power supply voltage Vcc1 from the high side driver 6 is thus divided by the resistors R1 and R2 to provide direct current (DC) voltage V2, and the DC voltage V2 is applied to the gate of the N-type FET Qn.

The N-type FET Qn outputs an off signal to the dead time control circuit 2 on the switching element S2 side when the off state of the switching element S1 is detected. Upon reception of the off signal, the dead time control circuit 2 on the switching element S2 side terminates an operation of delaying an ON period of the switching element S2 and immediately gives an ON signal to the switching element S2. Accordingly, the switching element S2 is turned on after the switching element S1 is reliably turned off, so that the switching elements S1 and S2 do not conduct electricity at the same time.

The monitor circuit 12 has a same structure as that of the monitor circuit 11. Power supply voltage Vcc2 from the low side driver 3 is divided by resistors R1 and R2 to provide DC voltage V2, and the DC voltage V2 is applied to the gate of an N-type FET Qn.

Upon detection of the off state of the switching element S2, the N-type FET Qn outputs an OFF signal to the dead time control circuit 4 on the switching element S1 side. The dead time control circuit 4 on the switching element S1 side terminates an operation of delaying the on period of the switching element S1 and immediately gives an on signal to the switching element S1. Accordingly, the switching element S1 is turned on after the switching element S2 is reliably turned off, so that the switching elements S1 and S2 do not conduct electricity at the same time.

The DC voltage V2 obtained by voltage division is set to a sum of the threshold value VTH of the switching element S1 at the output stage and the threshold value of the N-type FET Qn. As illustrated in FIG. 9B, when the gate voltage VG1 is reduced to the threshold value VTH or less, that is when the switching element S1 is turned off, a voltage of the threshold value of the N-type FET Qn or more is generated between the gate and source of the N-type FET Qn, thus allowing conduction between the drain and source of the N-type FET Qn. The drain voltage of the N-type FET Qn is discharged by the gate voltage VG1 and inverted into an L-level signal. In such a manner, the N-type FET Qn outputs the off-signal to the dead time control circuit 2 on the switching element S2 side upon detection of the off state of the switching element S1.

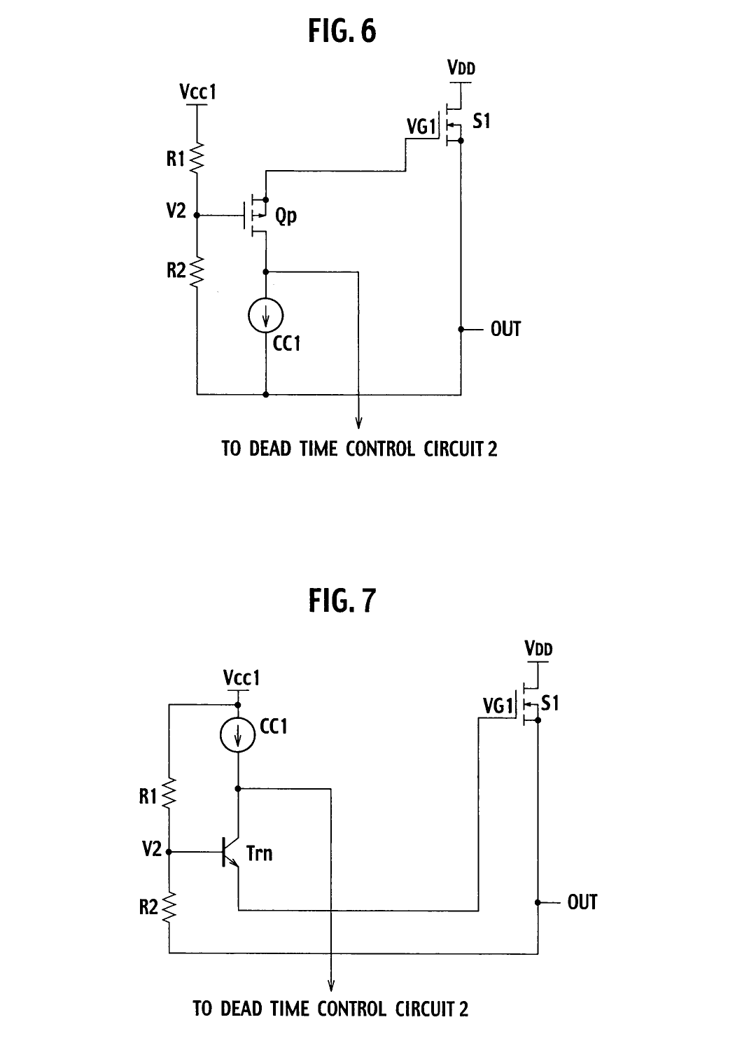

FIG. 6 is a diagram illustrating a second example of the gate drive circuit according to the first embodiment of the present invention. The second example is characterized by including a P-type FETs Qp. The power supply voltage Vcc1 from the high side driver 6 is divided by the resistors R1 and R2 to provide the DC voltage V2, and the DC voltage V2 is applied to the gate of the P-type FET Qp. The source of the P-type FET Qp is connected to the gate of the switching element S1, and the drain of the P-type FET Qp is connected to an end of the current source CC1. As illustrated in FIG. 9(b), when the gate voltage VG1 is reduced to the threshold value VTH or less, that is, when the switching element S1 is turned off, the voltage between the gate and source of the P-type FET Qp becomes a voltage of the threshold value of the P-type FET Qp or less, thus blocking conduction between the drain and source of the P-type FET Qp. The drain voltage of the P-type FET Qp is discharged by the current source CC1 and inverted into an L-level signal. In such a manner, when the off state of the switching element S1 is detected, the P-type FET Qp outputs the off-signal to the dead time control circuit 2 on the switching element S2 side.

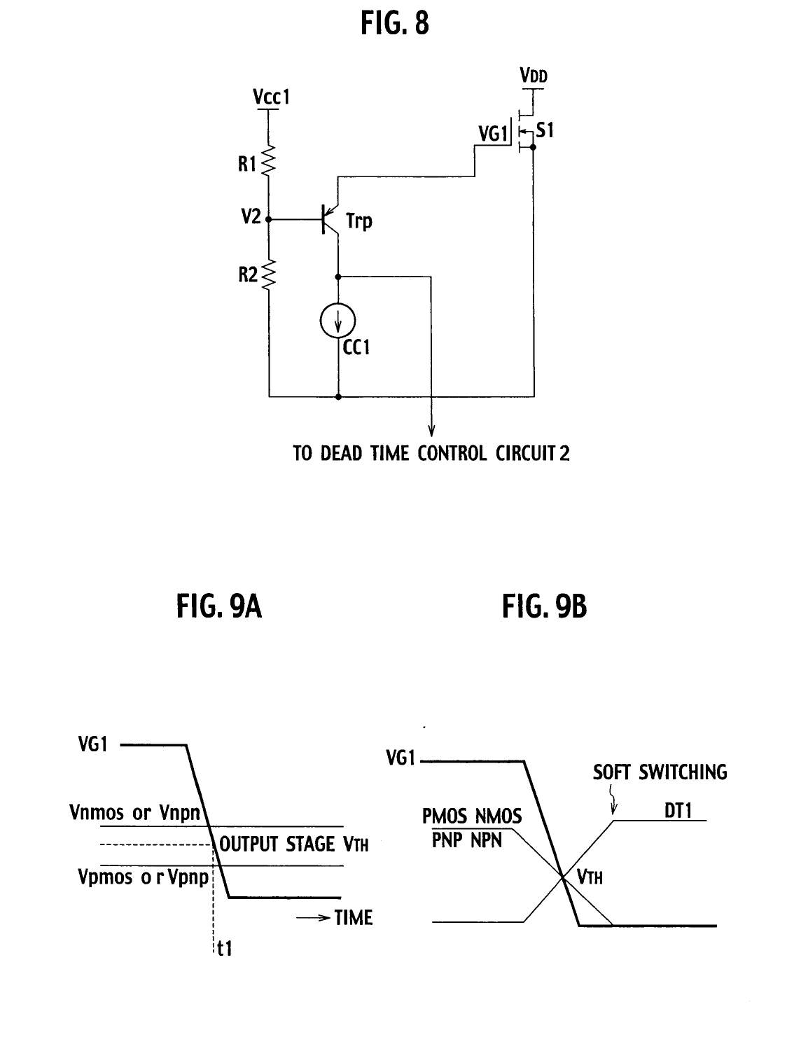

FIG. 7 is a diagram illustrating a third example of the gate drive circuit according to the first embodiment of the present invention. The third example illustrated in FIG. 7 is an example using an NPN transistor Trn as the detector transistor composed of a bipolar transistor and has the same circuitry as that in the case of the N-type FET Qn. FIG. 8 is a diagram of a fourth example of the gate drive circuit according to the first embodiment of the present invention. The fourth example illustrated in FIG. 8 is an example using a PNP transistor Trp as a detector transistor composed of a bipolar transistor and has the same circuitry as that in the case of the P-type FET Qp.

In each of FIGS. 7 and 8, voltage applied to the base of the transistor is set equal to or a little higher than a value as defined by (base voltage (gate threshold voltage) of the detector transistor)+(gate threshold voltage of the switching element). Even if the set voltage is equal to a value as defined by (gate threshold voltage (or base voltage) of the detector transistor)+(gate threshold voltage of the switching element), there is a delay between the time when the monitor circuits 11 and 12 output the off signal and the time when the switching elements S1 and S2 are turned on, so that the two switching elements S1 and S2 are less likely to be on simultaneously. However, in order to obtain quicker response, the set voltage should be set a little higher than the value of (gate threshold voltage (or base voltage) of the detector transistor)+(gate threshold voltage of the switching element). This makes it possible to compensate the delay in response between the time when the detector transistor detects the off state of one of the switching elements and the time when the dead time control circuit on the other switching element side terminates the operation of delaying.

### Second Embodiment

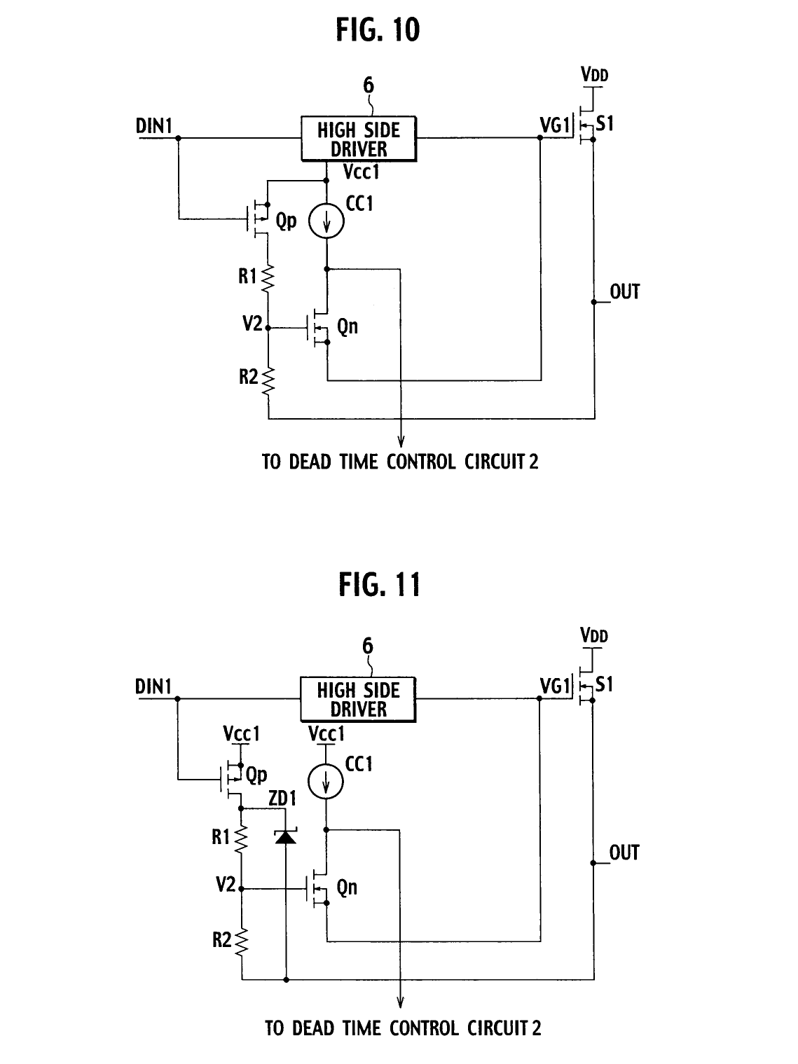

FIG. 10 is a diagram illustrating a gate drive circuit according to a second embodiment of the present invention. The second embodiment illustrated in FIG. 10 is characterized by further including a P-type FET Qp as a shutoff means constituting a power saving circuit in the monitor circuit of the first embodiment illustrated in FIG. 5.

The source of the P-type FET Qp is connected to the power supply voltage Vcc1; the drain of the P-type FET Qp is connected to an end of the resistor R1; and the gate of the P-type FET Qp is connected to an input voltage DIN1 of the high side driver 6. When the voltage DIN1 is turned off (when a signal is inputted from the other monitor circuit 12), the P-type FET Qp is turned on, and the voltage V2, which is obtained by dividing the power supply voltage Vcc1 by the resistors R1 and R2, is applied to the gate of the N-type FET Qn to turn on the N-type FET Qn.

When the voltage DIN1 is high (when a signal from the other monitor circuit 12 is not inputted), the P-type FET Qp is turned off to shutoff current across the resistors R1 and R2, thus reducing power consumption. Compared to the first embodiment in which the DC voltage is always applied to monitor the switching element, the monitor circuit of the second embodiment monitors the switching element only when the input voltage DIN1 is off and has an advantage in detecting turn-off of the switching element ST with less power consumption.

### Third Embodiment

FIG. 11 is a diagram illustrating a gate drive circuit according to a third embodiment of the present invention. The third embodiment illustrated in FIG. 11 is characterized by further including a Zener-diode ZD1 as a stabilization circuit in the monitor circuit of the second embodiment illustrated in FIG. 10. The cathode of the Zener-diode ZD1 is connected to the connection point of the drain of the P-type FET Qp and the resistor R1, and the anode thereof is connected to an end of the resistor R2.

The drain voltage of the P-type FET Qp is therefore clamped to breakdown voltage of the Zener diode ZD1, thus suppressing variations of the power supply voltage Vcc1 or variations of the divided voltage V2 due to variations of on resistance of the P-type FET Qp. This makes it possible to stably monitor the on/off states of the switching elements S1 and S2.

### Fourth Embodiment

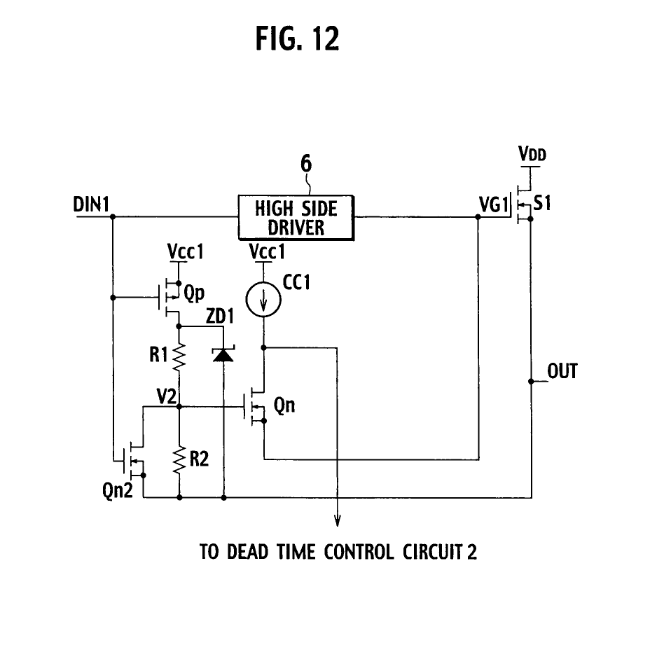

FIG. 12 is a diagram illustrating a gate drive circuit according to a fourth embodiment of the present invention. The fourth embodiment illustrated in FIG. 12 is characterized in the configuration of the third embodiment illustrated in FIG. 11 by further comprising an N-type FET Qn2 as a short-circuit means. The drain and source of the N-type FET Qn2 are connected to the both ends of the resistor R2, and the gate thereof is connected to the input voltage DIN1, thus improving the accuracy of the power saving switching.

With such a configuration, when the P-type FET Qp is turned off, charges stored at the connection point (V2) of the resistors R1 and R2 are discharged through the resistor R2, so that the voltage V2 is rapidly reduced to the minimum voltage.

The drain of the N-type FET Qn2 is connected to the gate of the N-type FET Qn. Accordingly, when the voltage DIN1 rises, simultaneously the N-type FET Qn2 comes into a conduction state while the P-type FET Qp comes into a shutoff state, thus allowing the charges stored at the connection point V2 to be discharged quickly. In such a manner, when the input voltage DIN1 goes high (an input of a signal from the other monitor circuit 12 is stopped), the N-type FET Qn2 is turned on, so that the N-type FET Qn can be turned off reliably and quickly.

When the signal from the other monitor circuit 12 is inputted to the gate of the N-type FET Qn2, the N-type FET Qn2 is turned off to apply voltage to the gate of the N-type FET Qn, thus turning on the N-type FET Qn.

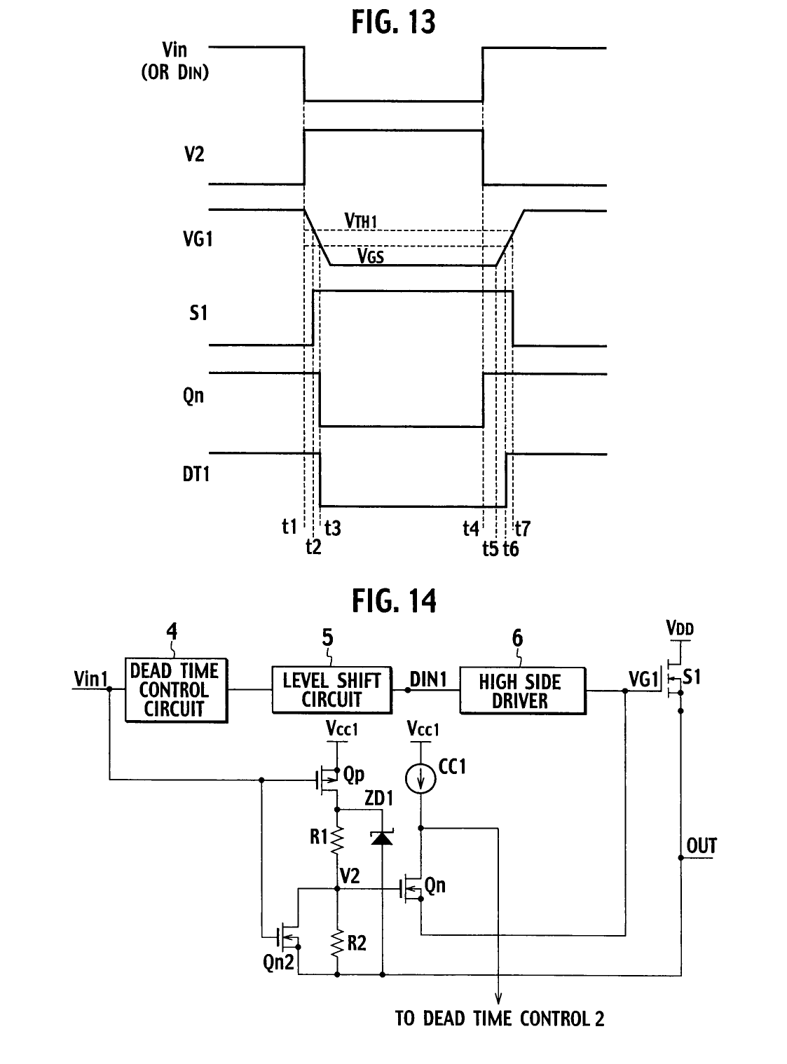

A description will be given of an operation of the monitor circuit illustrated in FIG. 12 with reference to the waveform diagram illustrated in FIG. 13. Until a time t1, the control signal Vin is high; and the switching elements S1 and S2 are on and off, respectively. At this time, the dead time control circuit 4 applies high to the high side driver 6 through the level shift circuit 5, and the high side driver 6 outputs high to keep the switching element S1 on.

At the same time, the dead time control circuit 2 receives the L level signal through the inverter 1 and outputs low to the low side driver 3 to keep the switching element off. At this time, in the monitor circuit 11, the H level signal is inputted as the voltage DIN1, and the N-type FET Qn2 is turned on while the P-type FET Qp is turned off. Accordingly, there is no voltage generated at the voltage V1 across the both ends of the series circuit of the resistors R1 and R2, and the connection point (V2) of the resistors R1 and R2 is short-circuited by the N-type FET Qn2, so that the N-type FET Qn is off. The drain voltage of the N-type FET Qn is equal to the power supply voltage Vcc1 through the current source CC1, and the H level signal is inputted into the dead time control circuit 2. However, the dead time control circuit 2 does not work upon receiving the H level signal.

Next, when the control signal Vin goes low from high at the time t1, the dead time control circuit 4 immediately outputs low through the level shift circuit 5 to cause the high side driver 6 to output high. The gate of the switching element S1 has a parasitic capacity and is not immediately turned off. The stored charges are discharged through the high side driver 6.

When the gate voltage VG1 of the switching element S1 is reduced to the threshold value VTH1 at a time t2, the switching element S1 is turned off to increase the voltage between the drain and source. At this time, in the monitor circuit 11, since the voltage DIN1 is low, the N-type FET Qn2 is turned off, and the P-type FET Qp is turned on.

The voltage V1 between the both ends of the series circuit of the resistors R1 and R2 becomes equal to power supply voltage Vcc1, and the voltage V2 across the both ends of the resistor R2 becomes equal to a voltage obtained by dividing the voltage V1 by the resistors R1 and R2. The voltage V2 is set to a value defined by (gate threshold value VGS of the N-type FET Qn)+(gate threshold value VTH1 of the switching element 1) or less. Accordingly, when the gate voltage VG1 of the switching element S1 is higher than the gate threshold value VTH1, the N-type FET Qn is off.

When the stored charges (holes) are discharged and the gate voltage VG1 of the switching element S1 is reduced to the gate threshold value VGS of the N-type FET Qn or less at a time t3, the switching element S1 is turned off, and the N-type FET Qn is turned on. Accordingly, current flows from the current source CC1 through the N-type FET Qn to the high side driver 6 which is outputting L level. At this time, since the drain voltage of the N-type FET Qn is low, the L level is outputted to the terminal DT1. In such a manner, when the control signal Vin goes low from high to turn the switching element S1 off, the monitor circuit 11 outputs low to the terminal DT1. The L level signal is inputted to the dead time control circuit 2, and the dead time control circuit 2 immediately terminates the operation of delaying to output high to the low side driver 3 and turn on the switching element S2.

When the control signal Vin goes to high from low at a time t4, the dead control circuit 4 delays the output. The monitor circuit 12 operates in the same way as the aforementioned monitor circuit 11 and, when the switching element S2 is turned off, outputs low to the terminal DT2.

When the terminal DT2 goes low at a time t5, the dead time control circuit 4 terminates the operation of delaying and gives an ON signal to the switching element S1. At a time t7, the switching element is thus turned on. The terminal DT1 of the monitor circuit 11 goes high at a time t6, but the dead time control circuit 2 does not operate when the terminal DT1 is high.

In such a manner, in the case of turning the switching element S1 on, the switching element S1 can be turned on after the monitor circuit 12 detects turn off of the switching element S2. In the case of turning the switching element S2 on, the switching element S2 can be turned on after the monitor circuit 11 detects turning off of the switching element S1. Accordingly, the switching elements S1 and S2 do not simultaneously conduct electricity.

The monitor circuits 11 and 12 detect the gate voltages of the switching elements S1 and S2 with the source voltages of the N-type FETs Qn as the detector transistors whose drains are connected to the current source CC1. Accordingly, even if the switching elements S1 and S2 are rapidly turned on/off, overshoot and ringing are prevented from being superimposed, and the on/off states of the switching elements S1 and S2 can be accurately detected.

### Fifth Embodiment

FIG. 14 is a diagram illustrating a gate drive circuit according to a fifth embodiment of the present invention. The fifth embodiment illustrated in FIG. 14 is characterized in that in the configuration of the fourth embodiment illustrated in FIG. 12, the voltages applied to the gates of the P-type and N-type FETs Qp and Qn2 are supplied from the control signal Vin.

Even if the voltages applied to the gates of the P-type and N-type FETs Qp and Qn2 are supplied from the control signal Vin in such a manner, a similar effect to that of the fourth embodiment can be obtained. Moreover, the control signal Vin determines the periods that the ON/OFF states of the switching elements S1 and S2 are monitored.

### EFFECT OF THE INVENTION

According to the first technical aspect of the present invention, the ON/OFF states of the switching elements can be detected with a simple circuit structure composed of a current source and detector transistors. Moreover, it is possible to provide a monitor circuit which does not cause chattering in the monitor signal even by quick turn on and off of the switching elements.

According to the second or third technical aspect of the present invention, the detector transistors are MOSFETs or bipolar transistors, and the drive voltage of the control terminal is set a little higher than (gate threshold voltage (base voltage) of the detector transistor)+(gate threshold voltage of the switching element)). It is therefore possible to compensate the response delay between the time when detector transistor detects the off state of one of the switching elements and the time when the dead time control circuit on the other switching element side terminates the operation of delaying.

According to the fourth technical aspect of the present invention, while the second control electrode does not receive a signal from the other monitor circuit, the power supply voltage applied to the first control electrode of the detector transistor is shut off. This can reduce unnecessary power consumption.

According to the fifth technical aspect of the present invention, while the third control electrode does not receive a signal from the other monitor circuit, the first control electrode of the detector transistor is short circuited to allow the detector transistor to be surely turned off. This makes it possible to reliably detect the off state of the switching element.

According to the sixth or seventh technical aspect of the present invention, the period that the switching elements are monitored can be determined by the control signal.

According to the eighth technical aspect of the present invention, the voltage applied to the fourth electrode of the shutoff means is stabilized by the stabilization circuit. It is therefore possible to detect the off state of the switching element stably even if the value of the control signal fluctuates.

This application claims benefit of priority under 35 USC §119 to Japanese Patent Application No. 2007-097309, filed on Apr. 3, 2007, the entire contents of which is incorporated by reference herein. Although the invention has been described above by reference to certain embodiments of the invention, the invention is not limited to the embodiments described above. Modifications and variations of the embodiments described above will occur to those skilled in the art, in light of the teachings. The scope of the invention is defined with reference to the following claims.

What is claimed is:

1. A gate drive circuit turning on/off alternately first and second switching elements connected in series according to a control signal, comprising:
a first dead time control circuit delaying an on period of the first switching element based on the control signal to generate a period when both the first and second switching elements are off;
a second dead time control circuit delaying an on period of the second switching element based on the control signal to generate a period when both the first and second switching elements are off;
a first drive circuit driving the first switching element based on a signal from the first dead time control circuit;
a second drive circuit driving the second switching element based on a signal from the second dead time control circuit;
a first monitor circuit monitoring an on/off state of the first switching element; and
a second monitor circuit monitoring an on/off state of the second switching element, wherein:
each of the first and second monitor circuits includes a current source and a detector transistor, a first electrode of the detector transistor being connected to a control terminal of one of the switching elements, a second electrode of the detector transistor being connected to the current source, and a predetermined voltage being applied to a first control electrode;
when an off state of the one switching element is detected, the detector transistor outputs an off signal to the dead time control circuit on the other switching element side; and
based on the off signal, the dead time control circuit on the other switching element side terminates an operation of delaying the on period of the other switching element.

2. The gate drive circuit of claim 1, wherein
the detector transistor is a MOSFET; and
the voltage applied to the first control electrode of the detector transistor is not less than a total voltage of a gate threshold voltage of the switching element and a gate threshold voltage of the detector transistor.

3. The gate drive circuit of claim 1, wherein
the detector transistor is a bipolar transistor; and
the voltage applied to the base of the detector transistor is not less than a total voltage of a gate threshold voltage of the switching element and a base threshold voltage of the detector transistor.

4. The gate drive circuit of claim 1, wherein:
each of the monitor circuits includes a shutoff means having a third electrode connected to a power source, a fourth electrode connected to the first control electrode of the detector transistor, and a second control electrode; and
the shutoff means applies power supply voltage to the first control electrode of the detector transistor as the signal from the other monitor circuit is inputted to the second control electrode and
shuts off the power supply voltage applied to the first control electrode of the detector transistor as the signal from the other monitor circuit is not inputted to the second control electrode.

5. The gate drive circuit of claim 1, wherein:
each of the monitor circuits includes a short circuit means having a fifth electrode connected to the first control electrode of the detector transistor, a sixth electrode, and a third control electrode; and
the short-circuit means applies the power supply voltage to the first control electrode of the detector transistor as the signal from the other monitor circuit is inputted into the third control electrode and
short-circuits the first control electrode of the detector transistor as the signal from the other monitor circuit is not inputted into the third control electrode.

6. The gate drive circuit of claim 1, wherein:
each of the monitor circuits includes a shutoff means having a third electrode connected to a power source, a fourth electrode connected to the first control electrode of the detector transistor, and a second control electrode; and
the shutoff means applies power supply voltage to the first control electrode of the detector transistor as the control signal is inputted to the second control electrode and
shuts off the power supply voltage applied to the first control electrode of the detector transistor as the control signal is not inputted to the second control electrode.

7. The gate drive circuit of claim 1, wherein:
each of the monitor circuits includes a short circuit unit having a fifth electrode connected to the first control electrode of the detector transistor, a sixth electrode, and a third control electrode; and
the short-circuit unit applies power supply voltage to the first control electrode of the detector transistor as the control signal is inputted to the third control electrode and
short-circuits the first control electrode of the detector transistor as the control signal is not inputted to the third control electrode.

8. The gate drive circuit of claim 4, wherein
each of the monitor circuits includes a stabilization circuit which is connected to the fourth electrode of the shutoff means and configured to stabilize voltage applied to the fourth electrode of the shutoff means.

9. The gate drive circuit of claim 6, wherein
each of the monitor circuits includes a stabilization circuit which is connected to the fourth electrode of the shutoff means and configured to stabilize voltage applied to the fourth electrode of the shutoff means.
